(19) United States
(12) Patent Application Publication
(10) Pub. No.: US 2024/0164153 A1
(43) Pub. Date: May 16, 2024

(54) MOTHER SUBSTRATE FOR DISPLAY DEVICE AND MANUFACTURING METHOD OF DISPLAY DEVICE

(71) Applicant: Japan Display Inc., Tokyo (JP)

(72) Inventor: Shinichi KAWAMURA, Tokyo (JP)

(73) Assignee: Japan Display Inc., Tokyo (JP)

(21) Appl. No.: 18/483,535

(22) Filed: Oct. 10, 2023

(30) Foreign Application Priority Data
Nov. 11, 2022 (JP) 2022-180947

(51) Int. Cl. H10K 59/126; H10K 59/12; H10K 59/122; H10K 59/80

(52) U.S. Cl. CPC H10K 59/126; H10K 59/1201; H10K 59/122; H10K 59/873

(57) ABSTRACT

According to one embodiment, a mother substrate for a display device includes an insulating substrate including a first main surface and a second main surface, a conductive shielding layer provided in the first main surface or the second main surface, and first and second panel portions overlapping the shielding layer. Each of the first panel portion and the second panel portion includes a display area which displays an image and a surrounding area outside the display area. The shielding layer includes a first shielding portion overlapping the first panel portion, a second shielding portion overlapping the second panel portion, and a connection portion provided for connecting the first shielding portion to the second shielding portion and formed into a belt-like shape.

### CROSS-REFERENCE TO RELATED APPLICATIONS

This application is based upon and claims the benefit of priority from Japanese Patent Application No. 2022-180947, filed Nov. 11, 2022, the entire contents of which are incorporated herein by reference.

### FIELD

Embodiments described herein relate generally to a mother substrate for a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a cross-sectional view showing an example of the display device DSP along the A-B line of FIG. 2.

FIG. 4 is a cross-sectional view showing another example of the display device DSP along the A-B line of FIG. 2.

FIG. 5 is a plan view showing an example of a shielding layer 110 formed in a mother substrate 100 for a display device.

FIG. 6 is a plan view showing an example of the mother substrate 100.

FIG. 7 is a cross-sectional view taken along the C-D line of the mother substrate 100 shown in FIG. 6.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a plan view showing another example of the shielding layer 110 formed in the mother substrate 100.

FIG. 16 is a plan view showing another example of the mother substrate 100.

FIG. 17 is a plan view showing another example of the shielding layer 110 formed in the mother substrate 100.

FIG. 18 is a plan view showing another example of the mother substrate 100.

FIG. 19 is a cross-sectional view taken along the E-F line of the mother substrate 100 shown in FIG. 18.

### DETAILED DESCRIPTION

In general, according to one embodiment, a mother substrate for display device comprises an insulating substrate comprising a first main surface and a second main surface on an opposite side of the first main surface, a conductive shielding layer provided in the first main surface or the second main surface of the insulating substrate, and first and second panel portions provided on the first main surface side of the insulating substrate and overlapping the shielding layer. Each of the first panel portion and the second panel portion comprises a display area which displays an image and a surrounding area outside the display area. The shielding layer comprises a first shielding portion overlapping the first panel portion, a second shielding portion spaced apart from the first shielding portion and overlapping the second panel portion, and a connection portion provided for connecting the first shielding portion to the second shielding portion and formed into a belt-like shape.

According to another embodiment, a manufacturing method of a display device comprises forming a conductive shielding layer in a first main surface of an insulating substrate or a second main surface on an opposite side of the first main surface, and forming a first panel portion and a second panel portion on the first main surface side of the insulating substrate so as to overlap the shielding layer. Each of the first panel portion and the second panel portion is formed so as to comprise a display area which displays an image and a surrounding area outside the display area. The shielding layer is formed so as to comprise a first shielding portion overlapping the first panel portion, a second shielding portion spaced apart from the first shielding portion and overlapping the second panel portion, and a connection portion provided for connecting the first shielding portion to the second shielding portion and formed into a belt-like shape.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

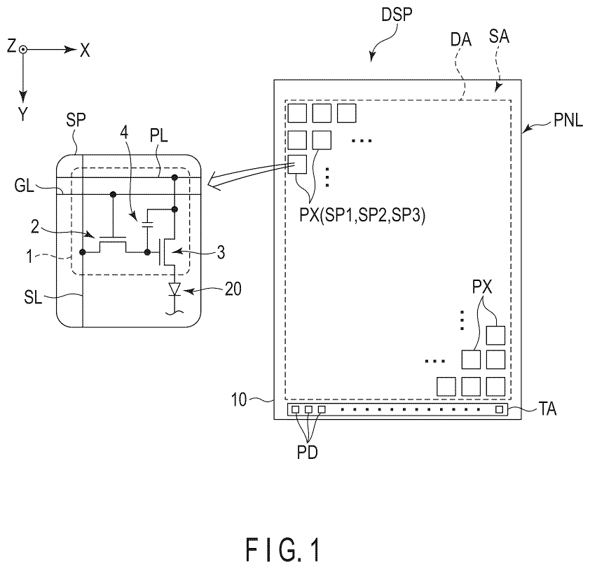

FIG. 1 is a diagram showing a configuration example of a display device DSP.

The display device DSP comprises a display panel PNL comprising a display area DA which displays an image and a surrounding area SA located on an external side relative to the display area DA on an insulating substrate 10. The insulating substrate 10 may be glass or a resinous film having flexibility.

In the present embodiment, the insulating substrate 10 is rectangular in plan view. It should be noted that the shape of the insulating substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a terminal area TA for connecting an IC chip and a flexible printed circuit. The terminal area TA comprises a plurality of pads (terminals) PD. The pads PD are connected to the terminal of the IC chip and the terminal of the flexible printed circuit.

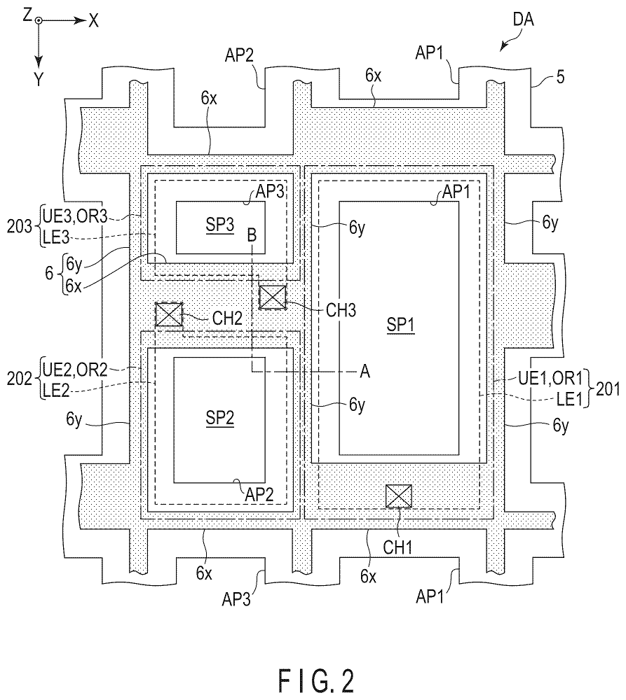

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 in plan view. The partition 6 is formed into a grating shape surrounding the apertures AP1, AP2 and AP3. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers or upper electrodes shown in the figure does not necessarily reflect the accurate shape.

The peripheral portion of each of the lower electrodes LE1, LE2 and LE3, the peripheral portion of each of the organic layers OR1, OR2 and OR3 and the peripheral portion of each of the upper electrodes UE1, UE2 and UE3 overlap the rib 5 in plan view.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

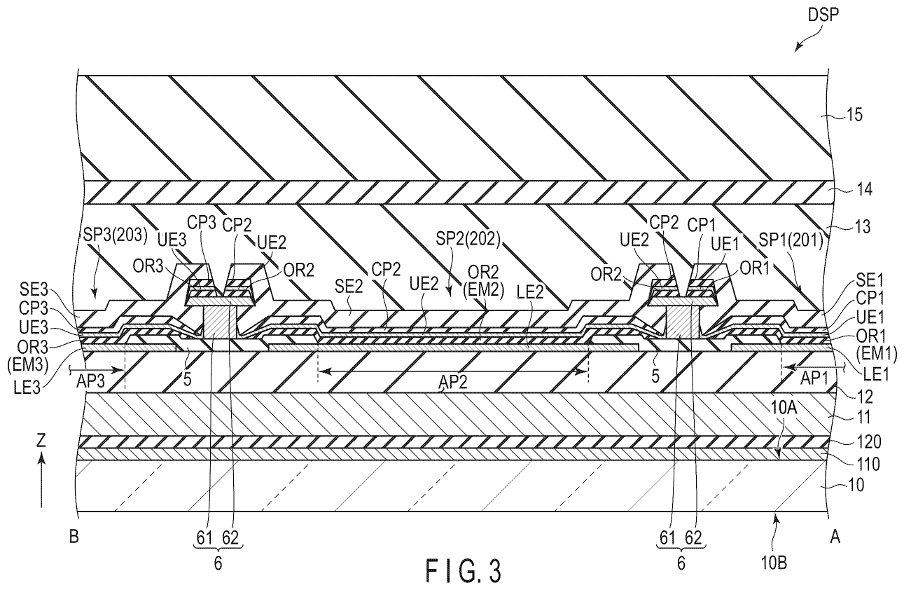

FIG. 3 is a cross-sectional view showing an example of the display device DSP along the A-B line of FIG. 2.

The insulating substrate 10 comprises a first main surface (inner surface) 10A and a second main surface (outer surface) 10B located on the opposite side of the first main surface 10A. A conductive shielding layer 110 is provided in the first main surface 10A. In the example shown in FIG. 3, the shielding layer 110 is provided so as to be in contact with the first main surface 10A. However, an insulating layer may be interposed between the insulating substrate 10 and the shielding layer 110. The shielding layer 110 is covered with an insulating layer 120.

A circuit layer 11 is provided on the insulating layer 120. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The rib 5 is provided on the insulating layer 12 and the lower electrodes LE1, LE2 and LE3. The aperture AP1 of the rib 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the rib 5. Between, of the lower electrodes LE1, LE2 and LE3, the lower electrodes which are adjacent to each other, the insulating layer 12 is covered with the rib 5. The lower electrodes LE1, LE2 and LE3 are connected to the pixel circuits 1 of subpixels SP1, SP2 and SP3, respectively, through the contact holes provided in the insulating layer 12.

The partition 6 includes a conductive lower portion (stem) 61 provided on the rib 5 and an upper portion (hat) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. By this configuration, the both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the rib 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the rib 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the rib 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the lower and upper portions 61 and 62 of the partition 6 and continuously covers each member of subpixel SP1.

The sealing layer SE2 is provided on the cap layer CP2, is in contact with the lower and upper portions 61 and 62 of the partition 6 and continuously covers each member of subpixel SP2.

The sealing layer SE3 is provided on the cap layer CP3, is in contact with the lower and upper portions 61 and 62 of the partition 6 and continuously covers each member of subpixel SP3.

In the example of FIG. 3, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

The material of the shielding layer 110 is one of metal such as silver or aluminum, a transparent conductive oxide such as indium tin oxide (ITO) and a semiconductor such as amorphous silicon (a-Si).

The insulating layer 120 is formed of, for example, an inorganic insulating material such as silicon nitride (SiNx), silicon oxide (SiOx), silicon oxynitride (SiON) or aluminum oxide (Al₂O₃).

Each of the rib 5, the sealing layers SE1, SE2 and SE3 and the sealing layer 14 is formed of, for example, an inorganic insulating material such as silicon nitride (SiNx). Each of the rib 5, the sealing layers SE1, SE2 and SE3 and the sealing layer 14 may be formed of another inorganic insulating material such as silicon oxide (SiOx), silicon oxynitride (SiON) or aluminum oxide (Al₂O₃).

Of the partition 6, at least the lower portion 61 is formed of a conductive material and is electrically connected to the upper electrodes UE1, UE2 and UE3.

Each of the lower electrodes LE1, LE2 and LE3 is formed of, for example, a stacked layer body consisting of a metal electrode (reflecting electrode) formed of metal such as silver (Ag) and a transparent electrode formed of a transparent conductive oxide such as ITO.

Each of the organic layers OR1, OR2 and OR3 includes a plurality of functional layers such as a hole injection layer, a hole transport layer, an electron blocking layer, a hole blocking layer, an electron transport layer and an electron injection layer.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices which are different from each other.

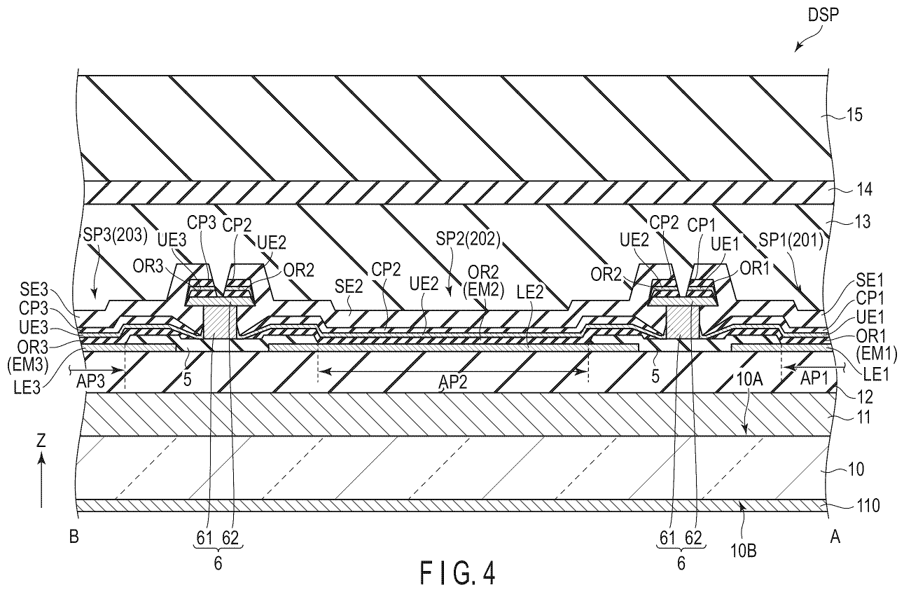

FIG. 4 is a cross-sectional view showing another example of the display device DSP along the A-B line of FIG. 2.

The example shown in FIG. 4 is different from the example shown in FIG. 3 in respect that the conductive shielding layer 110 is provided in the second main surface 10B of the insulating substrate 10. The shielding layer 110 is provided so as to be in contact with the second main surface 10B. However, an insulating layer may be interposed between the insulating substrate 10 and the shielding layer 110. The shielding layer 110 may be covered with another insulating layer.

The circuit layer 11 is provided on the insulating substrate 10.

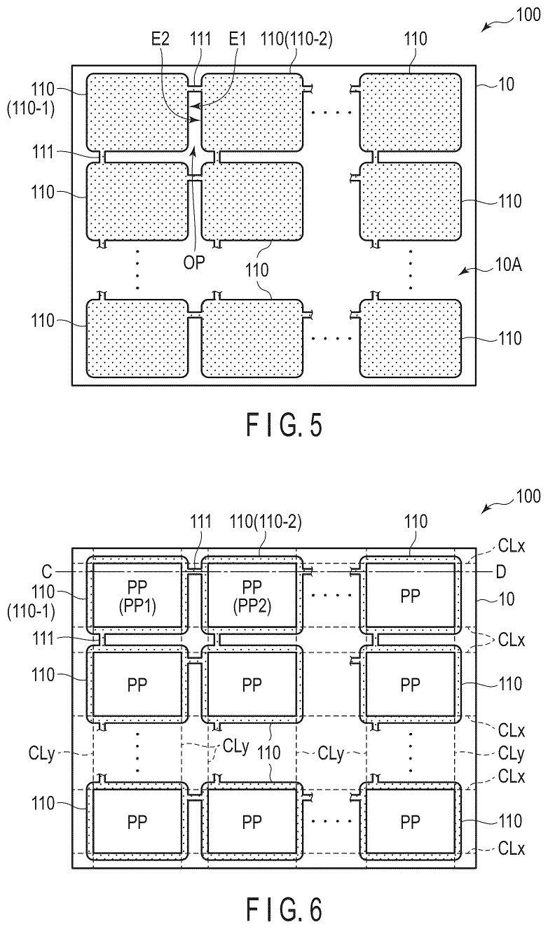

Now, this specification explains the manufacturing method of the display device DSP shown in FIG. 3. Here, this specification explains the manufacturing method of the mother substrate 100 for manufacturing a plurality of display devices DSP in a lump with reference to FIG. 5 to FIG. 7.

First, as shown in FIG. 5, the shielding layer 110 is formed in the first main surface 10A of the large insulating substrate 10. The shielding layer 110 comprises n shielding portions 110 (n being an integer greater than or equal to 2) each formed into an island-like shape, and a connection portion 111 for connecting the shielding portions 110 which are adjacent to each other.

In the example shown in the figure, a first shielding portion 110-1 and a second shielding portion 110-2 are formed on the insulating substrate 10 as the shielding portions 110. The second shielding portion 110-2 is spaced apart from the first shielding portion 110-1. Each connection portion 111 is formed into a belt-like shape having a width less than that of each shielding portion 110. Here, the width is defined as a length in a direction orthogonal to the direction in which the first shielding portion 110-1 and the second shielding portion 110-2 are arranged.

The first shielding portion 110-1 comprises a first edge portion E1 facing the second shielding portion 110-2. The second shielding portion 110-2 comprises a second edge portion E2 facing the first shielding portion 110-1. An opening OP (the area in which the shielding layer is not present) is formed between the first edge portion E1 and the second edge portion E2. In other words, in the example shown in the figure, the shielding layer 110 comprises the opening OP between the shielding portions 110 which are adjacent to each other.

This shielding layer 110 is covered with the insulating layer 120 shown in FIG. 3.

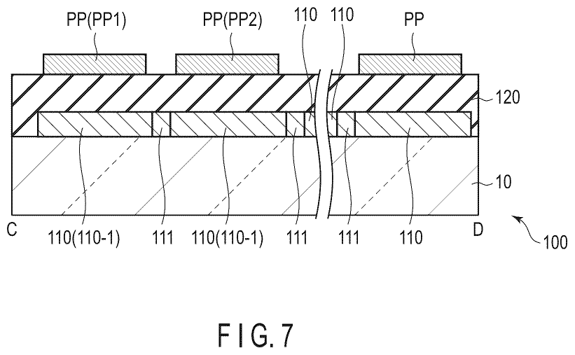

Subsequently, as shown in FIG. 6, n panel portions PP (n being an integer greater than or equal to 2) are formed in a lump so as to overlap the shielding layer 110. By this process, the mother substrate 100 for the display device is completed. FIG. 7 is a cross-sectional view taken along the C-D line of the mother substrate 100 shown in FIG. 6.

In the example shown in the figure, a first panel portion PP1 and a second panel portion PP2 are formed as the panel portions PP. The second panel portion PP2 is spaced apart from the first panel portion PP1. The first panel portion PP1 is provided on the insulating layer 120 and overlaps the first shielding portion 110-1. The second panel portion PP2 is provided on the insulating layer 120 and overlaps the second shielding portion 110-2.

The area of the first shielding portion 110-1 is greater than that of the first panel portion PP1. The area of the second shielding portion 110-2 is greater than that of the second panel portion PP2. In this manner, when the area of each shielding portion 110 is compared with that of each panel portion PP, each shielding portion 110 is formed so as to be larger than each panel portion PP. Each shielding portion 110 extends to the external side relative to the peripheral portion of a corresponding panel portion PP in plan view.

Subsequently, the mother substrate 100 is divided along a cut line CL. The cut line CL includes a plurality of first cut lines CLx extending in the direction in which the first panel portion PP1 and the second panel portion PP2 are arranged, and a plurality of second cut lines CLy intersecting with the first cut lines CLx.

The n shielding portions 110 including the first shielding portion 110-1 and the second shielding portion 110-2 overlap the first cut lines CLx and the second cut lines CLy. Each connection portion 111 is located between the first cut lines CLx which are adjacent to each other and between the second cut lines CLy which are adjacent to each other.

Each panel portion PP extracted by dividing the mother substrate 100 along the first cut lines CLx and the second cut lines CLy corresponds to the display panel PNL shown in FIG. 1. Thus, each of the n panel portions PP comprises the display area DA and the surrounding area SA as shown in FIG. 1. Further, as shown in FIG. 3, each of the n panel portions PP comprises the lower electrodes LE1, LE2 and LE3, the organic layers OR1, OR2 and OR3, the upper electrodes UE1, UE2 and UE3, the cap layers CP1, CP2 and CP3 and the sealing layers SE1, SE2 and SE3 in subpixels SP1, SP2 and SP3 of the display area DA. Each of the n shielding portions 110 corresponds to the shielding layer 110 shown in FIG. 3.

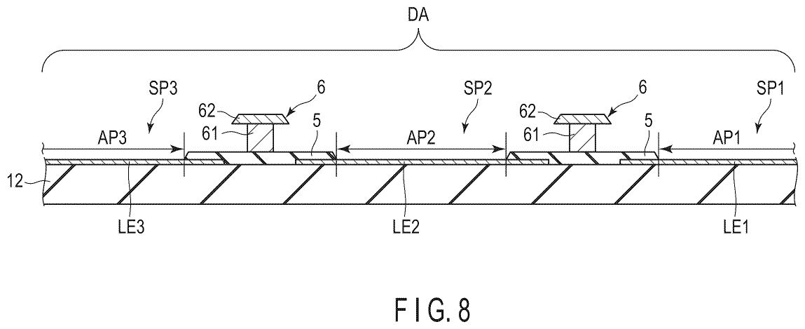

Now, this specification explains the specific manufacturing method for forming each of the n panel portion PP shown in FIG. 6. Here, this specification explains the manufacturing method of the display elements 201, 202 and 203 provided in the display area DA with reference to FIG. 8 to FIG. 14. In FIG. 8 to FIG. 14, the illustration of the lower side of the insulating layer 12 is omitted.

First, as shown in FIG. 8, after the lower electrodes LE1, LE2 and LE3 are formed on the insulating layer 12, the rib 5 comprising the apertures AP1, AP2 and AP3 and the partition 6 comprising the lower portion 61 and the upper portion 62 are formed. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3. It should be noted that the partition 6 comprising the lower portion 61 and the upper portion 62 may be formed after the formation of the rib 5 comprising the apertures AP1, AP2 and AP3. Alternatively, the apertures AP1, AP2 and AP3 may be formed after the formation of the partition 6.

Subsequently, the display element 201 is formed.

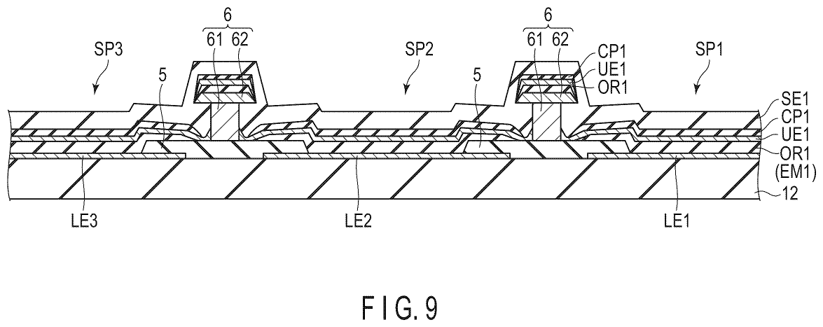

First, as shown in FIG. 9, the organic layer OR1 including the hole injection layer, the hole transport layer, the electron blocking layer, the light emitting layer (EM1), the hole blocking layer, the electron transport layer, the electron injection layer, etc., is formed on the lower electrode LE1.

Subsequently, the upper electrode UE1 is formed on the organic layer OR1 by using a mixture of magnesium and silver. The upper electrode UE1 covers the organic layer OR1 and is in contact with the lower portion 61.

Subsequently, the cap layer CP1 which is a stacked layer body consisting of a high-refractive layer and a low-refractive layer is formed on the upper electrode UE1.

Subsequently, the sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

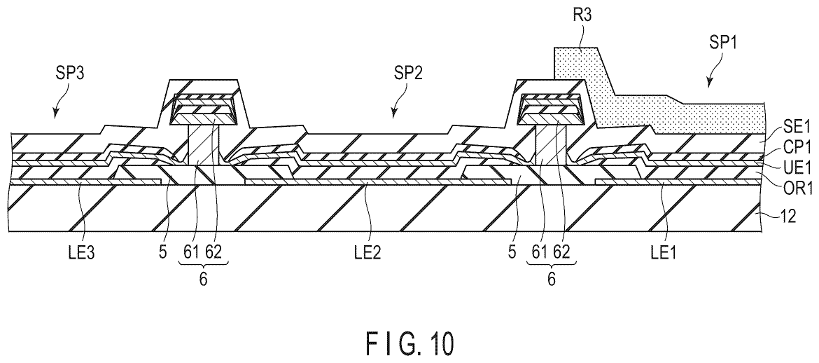

Subsequently, as shown in FIG. 10, a resist R3 having a predetermined shape is formed on the sealing layer SE1. The resist R3 covers subpixel SP1 and part of the partition 6 around subpixel SP1.

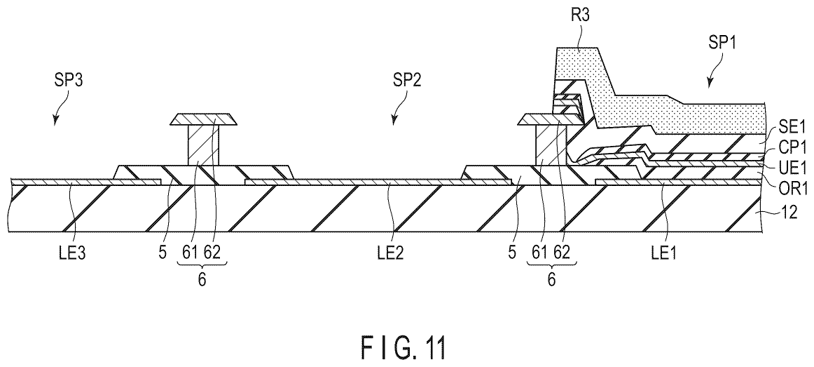

Subsequently, as shown in FIG. 11, the sealing layer SE1, cap layer CP1, upper electrode UE1 and organic layer OR1 exposed from the resist R3 are removed in series by etching using the resist R3 as a mask. In this manner, the lower electrode LE2 of subpixel SP2 and the lower electrode LE3 of subpixel SP3 are exposed.

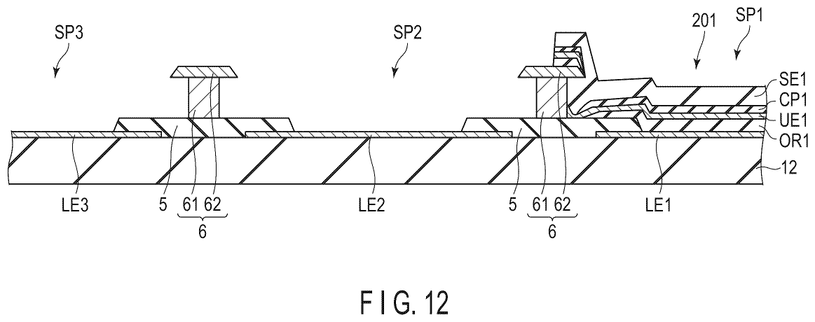

Subsequently, as shown in FIG. 12, the resist R3 is removed. By this process, the display element 201 is formed in subpixel SP1.

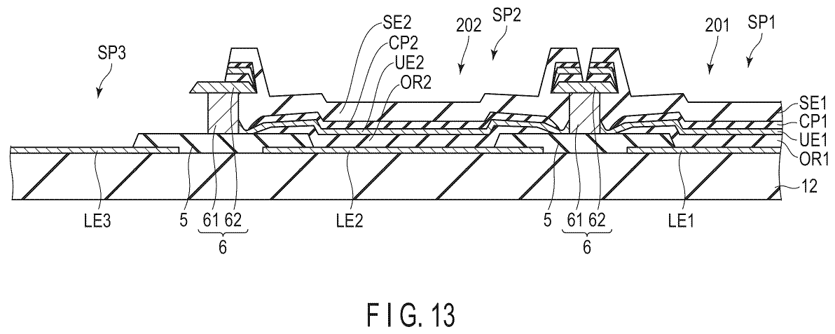

Subsequently, as shown in FIG. 13, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

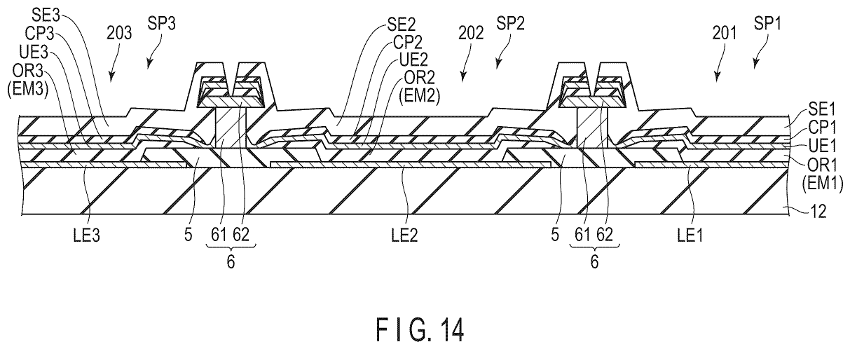

Subsequently, as shown in FIG. 14, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

In the manufacturing process of the display device DSP explained above, static electricity is easily generated at the time of contact or removal between the mother substrate 100 and various types of manufacturing devices (for example, an evaporation device, a CVD device, an etching device and a conveyance device). If such static electricity is locally stored in the mother substrate 100, a switching element or various lines formed near the portion may cause an electrostatic breakdown. In particular, in recent years, the downsizing or high definition of display devices has been considered. Thus, various circuits such as switching elements have been downsized, and various lines tend to be thinned. For this reason, the circuits and lines have a less capacity. Thus, an electrostatic breakdown is easily caused by the incursion of static electricity.

In the present embodiment, even if the mother substrate 100 is electrically charged by the static electricity generated in the manufacturing process of the display device DSP, as the shielding layer 110 is present, the static electricity generated in the manufacturing process is dispersed in the shielding layer 110, and thus, a uniform potential can be maintained in the entire shielding layer 110. Thus, the local storage of static electricity is prevented in the panel portion PP overlapping the shielding layer 110. Thus, the discharge between the panel portions PP which are adjacent to each other is prevented. Further, the electrostatic breakdown of the various circuits and various lines included in each of the n panel portions PP can be prevented. In this manner, the reduction in reliability in the manufacturing process can be prevented.

The shielding layer 110 overlaps the entire area of each of the n panel portions PP and comprises the opening OP between the panel portions PP which are adjacent to each other. Therefore, compared to a case where the shielding layer 110 is provided on the entire surface of the insulating substrate 10, the stress which could be generated in a thermal process is reduced, and the deformation of the substrate is prevented.

Now, this specification explains another manufacturing method of the display device DSP shown in FIG. 3.

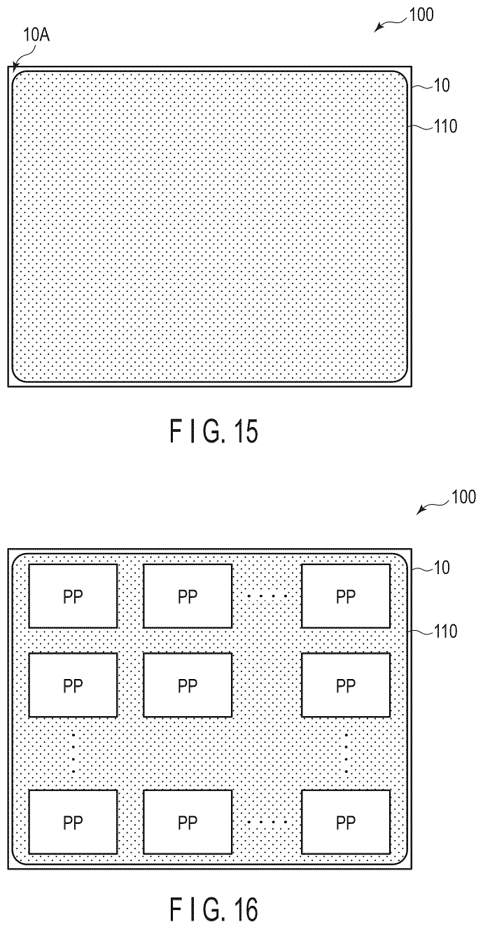

First, as shown in FIG. 15, the shielding layer 110 is formed in the first main surface 10A of the large insulating substrate 10. In the example shown in the figure, the shielding layer 110 is formed over substantially the entire surface of the insulating substrate 10. The formation of such a shielding layer 110 is based on the premise that the substrate is relatively small and the stress generated in a thermal process is sufficiently less.

This shielding layer 110 is covered with the insulating layer 120 shown in FIG. 3.

Subsequently, as shown in FIG. 16, a plurality of panel portions PP are formed in a lump so as to overlap the shielding layer 110. By this process, the mother substrate 100 for the display device is completed.

In this example, effects similar to those of the above description are obtained.

Now, this specification explains the manufacturing method of the display device DSP shown in FIG. 4.

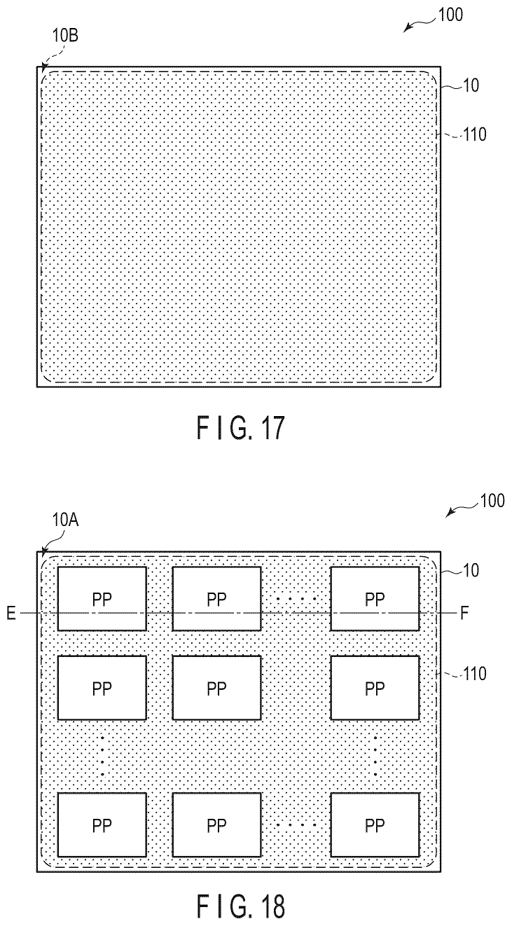

First, as shown in FIG. 17, the shielding layer 110 is formed in the second main surface 10B of the large insulating substrate 10. In the example shown in the figure, the shielding layer 110 is formed over substantially the entire surface of the insulating substrate 10.

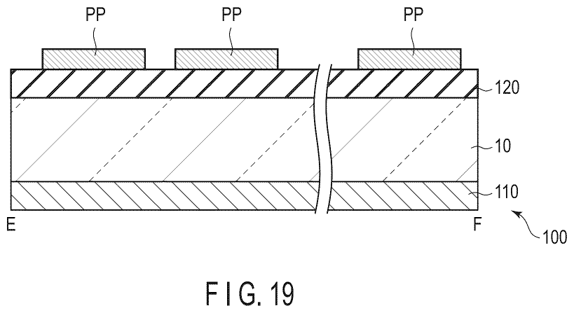

Subsequently, as shown in FIG. 18, a plurality of panel portions PP are formed in a lump in the first main surface 10A of the insulating substrate 10. Each of the panel portions PP overlaps the shielding layer 110 via the insulating substrate 10. By this process, the mother substrate 100 for the display device is completed. FIG. 19 is a cross-sectional view taken along the E-F line of the mother substrate 100 shown in FIG. 18. In the example shown here, each panel portion PP is formed on the opposite side of the shielding layer 110 across the intervening insulating substrate 10.

In this example, effects similar to those of the above description are obtained.

It should be noted that the shielding layer 110 shown in FIG. 17 and FIG. 18 may have a shape comprising the n shielding portions 110 and the connection portions 111 in a manner similar to that of the example shown in FIG. 5.

As explained above, the present embodiment can provide a mother substrate for the display device and a manufacturing method of a display device such that the reduction in reliability can be prevented.

All of the mother substrate for the display devices and the manufacturing methods of display devices that can be implemented by a person of ordinary skill in the art through arbitrary design changes to the mother substrate for the display device and the manufacturing method of a display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiment by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiment and are self-explanatory from the descriptions of the specification or can be arbitrarily conceived by a person of ordinary skill in the art are considered as the effects of the present invention as a matter of course.

What is claimed is:

1. A mother substrate for a display device comprising:
an insulating substrate comprising a first main surface and a second main surface on an opposite side of the first main surface;
a conductive shielding layer provided in the first main surface or the second main surface of the insulating substrate; and
first and second panel portions provided on the first main surface side of the insulating substrate and overlapping the shielding layer, wherein
each of the first panel portion and the second panel portion comprises a display area which displays an image and a surrounding area outside the display area, and
the shielding layer comprises:
a first shielding portion overlapping the first panel portion;
a second shielding portion spaced apart from the first shielding portion and overlapping the second panel portion; and
a connection portion provided for connecting the first shielding portion to the second shielding portion and formed into a belt-like shape.

2. The mother substrate of claim 1, wherein
an area of the first shielding portion is greater than an area of the first panel portion, and
an area of the second shielding portion is greater than an area of the second panel portion.

3. The mother substrate of claim 1, wherein
the shielding layer is formed of one of metal, a conductive oxide and a semiconductor.

4. The mother substrate of claim 1, wherein
the first shielding portion and the second shielding portion overlap a plurality of cut lines intersecting with each other, and
each of the connection portions is located between the cut lines adjacent to each other.

5. The mother substrate of claim 1, wherein
the display area comprises:
a lower electrode provided above the insulating substrate;
a rib formed of an inorganic insulating material and overlapping a peripheral portion of the lower electrode;
a partition which comprises a lower portion provided on the rib and formed of a conductive material, and an upper portion provided on the lower portion and protruding from a side surface of the lower portion;
an organic layer provided on the lower electrode and including a light emitting layer; and
an upper electrode which covers the organic layer and is in contact with the lower portion of the partition.

6. The mother substrate of claim 5, wherein
the display area further comprises:
a cap layer provided on the upper electrode; and
a sealing layer which is formed of an inorganic insulating material, is provided on the cap layer and is in contact with the lower portion of the partition.

7. The mother substrate of claim 1, wherein
a width of the connection portion is less than a width of each of the first shielding portion and the second shielding portion.

8. A manufacturing method of a display device, comprising:
forming a conductive shielding layer in a first main surface of an insulating substrate or a second main surface on an opposite side of the first main surface; and
forming a first panel portion and a second panel portion on the first main surface side of the insulating substrate so as to overlap the shielding layer, wherein
each of the first panel portion and the second panel portion is formed so as to comprise a display area which displays an image and a surrounding area outside the display area, and
the shielding layer is formed so as to comprise:
a first shielding portion overlapping the first panel portion;
a second shielding portion spaced apart from the first shielding portion and overlapping the second panel portion; and
a connection portion provided for connecting the first shielding portion to the second shielding portion and formed into a belt-like shape.

9. The manufacturing method of claim 8, wherein
an area of the first shielding portion is greater than an area of the first panel portion, and
an area of the second shielding portion is greater than an area of the second panel portion.

10. The manufacturing method of claim 8, wherein
the shielding layer is formed of one of metal, a conductive oxide and a semiconductor.

11. The manufacturing method of claim 8, wherein
a mother substrate for a display device, in which the first panel portion and the second panel portion are formed is divided along first and second cut lines intersecting with each other, and the first panel portion and the second panel portion are extracted as display panels,
the first shielding portion and the second shielding portion overlap the first and second cut lines, and
the connection portion is located between the first cut lines adjacent to each other and between the second cut lines adjacent to each other.

12. The manufacturing method of claim 8, wherein
a width of the connection portion is less than a width of each of the first shielding portion and the second shielding portion.
